(19) United States
(12) Patent Application Publication
(10) Pub. No.: US 2026/0177594 A1
(43) Pub. Date: Jun. 25, 2026

(54) DETECTION OF STOLEN UTILITY METERS

(71) Applicant: ITRON, INC., Liberty Lake, WA (US)

(72) Inventor: Gopakumar GOPINATHAN, Granite Bay, CA (US)

(21) Appl. No.: 19/001,045

(22) Filed: Dec. 24, 2024

(51) Int. Cl. G01R 22/06; G06Q 50/06

(52) U.S. Cl. CPC G01R 22/066; G06Q 50/06

(57) ABSTRACT

Various embodiments disclose a method comprising generating, by a central server, a list of locations where a stolen meter is likely to be used, identifying, by the central server, a first meter having one or more characteristics of a stolen meter, and in response to determining that a first location associated with the first meter meets one or more distance criteria relative to a second location on the list of locations, performing, by the central server, a remedial action in relation to the first meter.

### BACKGROUND

### Field of the Various Embodiments

The various embodiments relate generally to detection of stolen utility meters.

### Description of the Related Art

Smart utility meters electronically record the consumption of utility commodities, such as water, electricity, heat, and gas at assigned service points, such as houses and buildings. The smart utility meters then communicate with a central server/office of a utility provider/provider to transmit consumption information to the utility provider for billing purposes. If a particular smart utility meter is assigned to a particular service point that is associated with delinquent payment of utility bills, the central server of the utility provider can shut off the utility at the particular service point. For example, the central server can shut off the electricity at the particular service point, such as a customer's house, by sending a remote disconnect command to the assigned meter, which effectively disables the assigned meter from providing electricity to any type of load (service point).

### BRIEF DESCRIPTION OF THE DRAWINGS

So that the manner in which the features of the various embodiments can be understood in detail, a description of the inventive concepts may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a block diagram of a stolen meter detection system 100, according to various embodiments;

FIG. 2 illustrates a utility meter, according to various embodiments;

FIG. 3 illustrates central server, according to various embodiments;

FIG. 4 illustrates a conceptual diagram of the meter event table of FIG. 3, according to various embodiments;

FIG. 5 illustrates a conceptual diagram of the transformer table of FIG. 3, according to various embodiments;

FIG. 6 illustrates a conceptual diagram of the transformer discrepancy list of FIG. 3, according to various embodiments;

FIG. 7 illustrates a block diagram of commodity distribution system during a first stage of operation of the utility network system, according to various embodiments;

FIG. 8 illustrates a block diagram of a commodity distribution system during a second stage of operation of the utility network system, according to various embodiments;

FIG. 9 illustrates a block diagram of a commodity distribution system during a third stage of operation of the utility network system, according to various embodiments;

FIG. 10 is a flow diagram of method steps for an information collection phase, according to various embodiments;

FIG. 11 is a flow diagram of method steps for executing a theft-detection algorithm, according to various embodiments; and

FIG. 12 illustrates a utility network system configured to implement one or more aspects of the various embodiments.

### DETAILED DESCRIPTION

In the following description, numerous specific details are set forth to provide a more thorough understanding of the various embodiments. However, it will be apparent to one of skill in the art that the inventive concepts may be practiced without one or more of these specific details.

An illicit actor might want to steal a meter for any of a number of reasons. For example, when a utility meter is disabled due to lack of bill payment, some customers have resorted to removing their disabled meter, stealing a meter from a nearby service point, and installing the stolen meter at their own service point. Because the stolen meter has not been disabled by the central server, the stolen meter is still capable of providing electricity to a load (service point). For example, a first customer at a first service point can have a first meter that is disabled, and a second customer at a second service point can have a second meter that is stolen/removed by the first customer and then illicitly installed at the first service point. As another example, an illicit actor might be conducting activities at a location that consume a large amount of power that the illicit actor wants to conceal and/or for which they do not want to pay. Such situations are problematic as the electricity provided to the first customer at the first service point via the second/stolen meter will be billed to the second customer of the second service point. Also, an improperly installed stolen meter can be a fire hazard that can potentially start a fire at the first service point.

For the above reasons, detection and recovery of stolen meters is important for the utility provider. Typically, a stolen meter is visually detected by a worker or personnel of the utility provider. For example, a worker that is servicing a meter at a particular service point may detect a suspicious meter through a visual inspection that shows the seal around the meter is broken or missing, the meter or socket around the meter is dented, scratched, or otherwise damaged, or the meter is not properly installed into the socket. After visually detecting a suspicious meter, the worker can check the meter identifier (ID) of the suspicious meter and cross-check the meter ID with the meter ID associated with the particular service point stored at the central server. If the two meter IDs do not match, then the worker can flag the suspicious meter as a stolen meter to the central server.

However, the above conventional technique for detecting stolen meters can be highly random and inaccurate. First, a worker can be at the particular service point purely by chance, for example, to service a power outage in the area. Also, the worker oftentimes will not be able to visually detect a stolen meter depending on how well the customer installed the stolen meter. In addition, even if there are visible signs of an illicitly installed meter, the worker may simply not detect these visible signs. Finally, conventional techniques can provide false positives where a meter is flagged as a stolen meter, but is not in fact a stolen meter due to, for example, the wrong meter ID being associated with the particular service point at the central server.

In order to address these shortcomings, techniques are disclosed herein that enable automatic detection of stolen meters and the likely locations of the stolen meters. In the disclosed techniques, the central server executes a theft detection application that collects various information from a central data store and from a plurality of utility meters. The information collected from the central data store can include a meter event table and a transformer table. The information collected from the plurality of meters include various meter events that populate the meter event table and transformer beacons that populate the transformer table. The theft detection application executing on the central server then executes a theft-detection algorithm that identifies/flags stolen meters and likely locations of the stolen meters (referred to herein as flagged meters and flagged locations) based on the collected information. The theft-detection algorithm includes double-checking steps that can be implemented separately or in combination to increase the confidence that the flagged meters are in fact stolen meters and the flagged locations are in fact current locations of the stolen meters. The theft detection application executing on the central server can then perform a remedial action in relation to each flagged meter, such as causing an inspection of the flagged meter at a flagged location.

At least one technical advantage of the disclosed techniques is that, with the disclosed techniques, stolen meters and current locations of stolen meters can be automatically and systematically detected more quickly and with higher accuracy than conventional techniques. Because the disclosed techniques rely on a theft-detection algorithm that is executed automatically at the central server based on information collected from the central data store and the plurality of utility meters, the disclosed techniques do not rely on the highly random and inaccurate human detection of stolen meters, thus enabling detection of a greater number of stolen meters relative to conventional techniques. Also, because the theft-detection algorithm includes double-checking steps that increase the confidence in the flagged meters, the disclosed techniques also reduce the incidence of false positives where meters are erroneously flagged as stolen meters relative to conventional techniques. In this manner, utility providers can identify stolen meters within a reasonable time, which allows for faster recovery of the stolen meters, reduces the number of incorrect billings to customers at service points where the meters were stolen, and reduces fire hazards at service points where stolen meters were incorrectly installed.

### Detecting Stolen Utility Meters

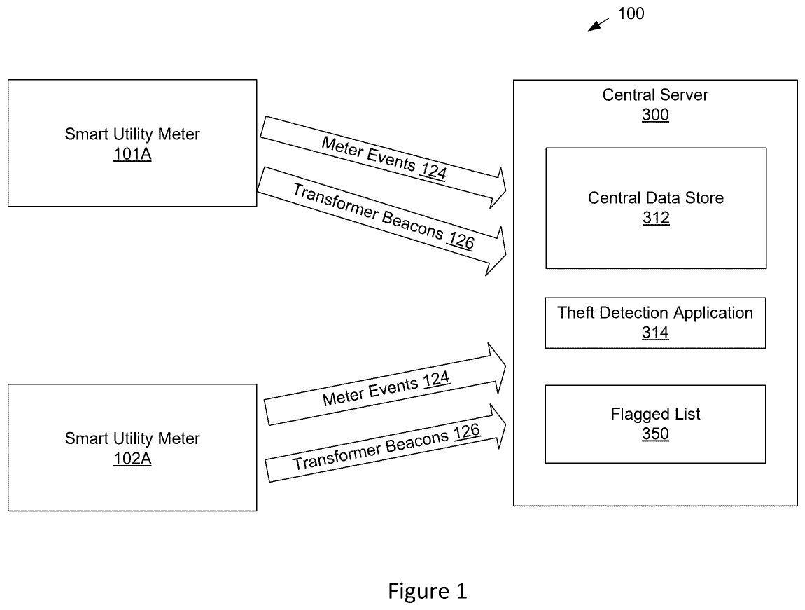

FIG. 1 illustrates a block diagram of a stolen meter detection system 100, according to various embodiments. As shown in FIG. 1, stolen meter detection system 100 includes, without limitation, a first smart utility meter 101A (hereinafter “first meter”), a second smart utility meter 102A (hereinafter “second meter”), and a central server 300. The devices 101A, 102A, and 300 are subparts of a utility network system (not shown).

The first meter 101A is located at a first service point at a first location, such as a first house, building, or other structure at which one or more utility commodities are consumed and second meter 102A is located at a second service point at a second location, such as a second house, building, or other structure at which one or more utility commodities are consumed. In some examples, central server 300 is a remote computing device located at a third location, such as a central office or other facility of a utility provider, or a third-party service associated with detecting stolen meters. Devices 101A, 102A, and 300 are connected by a communication medium (not shown). The communication medium can be, for example, a wired connection (e.g., an Ethernet connection or a power line communication connection), a wireless connection (e.g., a Wi-Fi connection, a Bluetooth connection, or any other type of wireless connection), or any combination thereof. Although not shown, devices 101A, 102A, and 300 can be in communication with other devices by the same communication medium or different communication media.

In normal operation, first and second meters 101A, 102A are configured to monitor and report consumption of utility commodities to central server 300 via the communication medium. In addition, first and second meters 101A, 102A are configured to detect and transmit various meter events 124 and transmit periodic transformer beacons 126 via the communication medium. The various meter events 124 can include, without limitation, a remote disconnect event, a power outage event, and a meter removal event. Each periodic transformer beacon 126 specifies a transformer ID that uniquely identifies a transformer to which the meter is currently connected. Although not shown in FIG. 1, first and second meters 101A, 102A can also share data with each other, for example, to determine the transformer to which each meter is currently connected.

The central server 300 includes a central data store 312, a theft detection application 314, and a flagged list 350. The central data store 312 includes transformer information for each transformer of the utility network system, meter information for each meter of the utility network system, a meter event table, a transformer table, and a discrepancy list. The central server 300 receives the meter events 124 from the first and second meters 101A, 102A, which are used to populate the meter event table. Each meter event 124 will have an associated timestamp indicating when the meter event 124 was generated and/or transmitted. The central server 300 also receives the transformer beacons 126 from the first and second meters 101A, 102A, which are used to populate the transformer table. The central server 300 executes the theft detection application 314 that collects various information from the central data store 312 and the first and second meters 101A, 102A and performs a theft-detection algorithm to generate the flagged list 350 based on the collected information. The flagged list 350 identifies/flags potential stolen meters and likely locations of the stolen meters (referred to herein as flagged meters and flagged locations) based on the collected information. The theft detection application can then perform a remedial action in relation to each flagged meter on the flagged list 350, such as causing an inspection of a flagged meter at a flagged location, generating a work order for a utility worker to inspect the flagged meter at the flagged location (for example, to verify if the flagged meter is a stolen meter or to inspect for signs of improper installation, etc.), or to cause a remote disconnection of the flagged meter at the flagged location (for example, by transmitting a remote disconnect command to the flagged meter).

### Smart Utility Meter

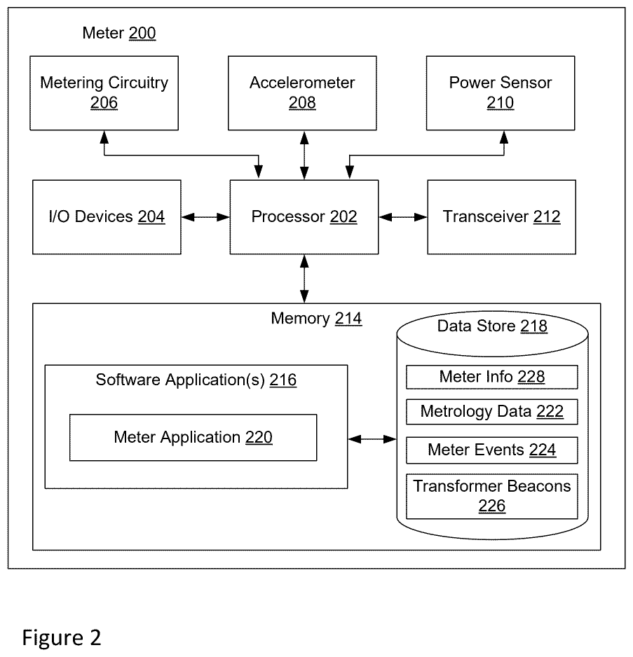

FIG. 2 illustrates a utility meter 200, according to various embodiments. In some embodiments, utility meter 200 is used to implement any utility meter, such as first meter 101A or second meter 102A of FIG. 1. For an electric meter, each utility meter 200 has two connection sides: a first line side which is connected to a transformer of the utility network system and a second load side which is connected to a load/service point, such as a house, building, or other structure. As shown, meter 200 includes, without limitation, processor 202, input/output (I/O) devices 204, metering circuitry 206, accelerometer 208, power sensor 210, transceiver 212, and memory 214, coupled together via a bus.

Processor 202 coordinates operations of meter 200. In various embodiments, processor 202 includes any hardware configured to process data and execute software applications. The processor 202 can be any technically feasible processing device configured to process data and execute program instructions. For example, processor 202 could include one or more central processing units (CPUs), DSPs, graphics processing units (GPUs), application-specific integrated circuits (ASICs), field-programmable gate arrays (FPGAs), microprocessors, microcontrollers, other types of processing units, and/or a combination of different processing units. Processor 202 can include a real-time clock (RTC) (not shown) according to which processor 202 maintains an estimate of the current time. The estimate of the current time can be expressed in Universal Coordinated Time (UTC), although any other standard of time measurement can also be used.

I/O devices 204 include devices configured to receive input, devices configured to provide output, and devices configured to both receive input and provide output. Metering circuitry 206 includes one or more data acquisition devices that are used by meter 200 to monitor consumption of a utility commodity (e.g., water, gas, electricity, etc.). For example, I/O devices 204 can further include one or more of an electricity meter, a gas meter, a water meter, or some other type of sensor used to monitor consumption of a utility commodity. In some embodiments, the I/O devices 204 include a GPS device that generates coordinates specifying a current location of the meter 200.

Accelerometer 208 is configured to sense movement, or acceleration, of meter 200. In some examples, accelerometer 208 senses acceleration of meter 200 along one or more axes, such as acceleration along an x-axis, y-axis, and/or z-axis relative to meter 200. The acceleration values sensed along each of the x, y, and z axes can be combined into an acceleration vector that is indicative of the movement, or acceleration, of meter 200. Meters 200 can include accelerometers for the purpose of detecting a user tampering with a meter. For example, based on an acceleration sensed by accelerometer 208, meter 200 can determine when someone is trying to remove meter 200 from a socket at the assigned service point/premises at which meter 200 monitors consumption of a utility commodity (e.g., electricity, water, or gas). In response to detecting that someone is trying to remove meter 200 from the socket, the meter 200 can generate and transmit a meter removal event to the central server 300.

Power sensor 210 is configured to sense whether power is currently being received by the meter 200 from its power source. The power source can be an external power source, such as mains electricity or a power grid and/or an internal power source, such as a battery. In response to detecting that the meter 200 is not currently receiving power from its power source, the meter 200 can generate and transmit a power outage event to the central server 300. In response to detecting that power has been restored to the meter 200 and is currently receiving power from its power source, the meter 200 can generate and transmit a power restoration event to the central server 300.

Transceiver 212 is configured to transmit and/or receive data to and from other devices, such as other meters 200, first meter 101A, second meter 102A, or central server 300. The transmitted and/or received data can include metrology data, meter events, transformer beacons and/or other messages. For example, transceiver 212 transmits one or more messages that include metrology data, various detected meter events, and/or periodic transformer beacons to the central server 300.

Memory 214 includes one or more software applications 216 and a data store 218, coupled together. As shown, the one or more software applications 216 include meter application 220. Data store 218 stores meter information 228, metrology data 222, meter events 224, and transformer beacons 226. The meter information 228 can include a meter ID and an assigned transformer ID. The meter ID can be assigned by the central server 300 that uniquely identifies the meter 200 within the utility network system. The assigned transformer ID can uniquely identify an assigned transformer within the utility network system that is initially assigned to the meter 200 by central server 300. In normal operation, the meter 200 should be coupled only to the assigned transformer and not to other transformers in the utility network system. In some embodiments, the meter information 228 also includes information associated with the location of meter 200, such as GPS coordinates, an address that identifies the location of meter 200, and/or the location of the service point (such as the building or structure) at which metering device 200 is installed. The metrology data 222 includes data indicative of a consumption of a utility commodity. The meter events 224 include various meter events that are detected by the meter 200, including, without limitation, remote disconnect events, power outage events, and meter removal events, whereby each event has an associated timestamp. Transformer beacons 226 are periodically generated by the meter 200 and specify a current transformer ID of a transformer to which the meter 200 is currently connected. In normal operation (when no meters have been stolen and illicitly installed), the current transformer ID should match the assigned transformer ID.

The meter application 220 which, when executed by processor 202, interfaces with one or more of accelerometer 208, power sensor 210, transceiver 212, and data store 218 to perform various functions to support the techniques for detecting stolen meters described herein. In this regard, the meter application 220 can receive and execute commands from the central server 300, detect and transmit various meter events 224 with timestamps to the central server 300, periodically transmit transformer beacons 226 to the central server 300, and transmit other types of messages, such as metrology data 222 to the central server 300.

For example, the meter application 220 can receive and execute a remote disconnect command from the central server 300. If a particular meter 200 is assigned to a particular service point that is associated with delinquent payment of utility bills, the central server 300 can shut off the utility commodity at the particular service point. For example, the central server 300 can shut off the electricity at the particular service point by sending a remote disconnect command to the meter 200 assigned to the particular service point. In response, the assigned meter 200 will execute the remote disconnect command and generate and transmit a remote disconnect event to the central server 300, which confirms the remote disconnect of the assigned meter 200. Each remote disconnect event will also have an associated timestamp indicating when the remote disconnect event was generated and/or transmitted. When a meter 200 is remote disconnected, the second load side of the meter 200 is disabled, thus the meter 200 is effectively disabled from providing electricity to any load/service point. When a meter 200 is remote disconnected, the meter 200 is still otherwise functional in that the first line side of the meter 200 remains connected to the transformer and is still in communications with the central server 300.

The meter application 220 can also detect and transmit a meter removal event to the central server 300. The meter application 220 can receive data from the accelerometer 208, such as acceleration values or acceleration vectors, to determine that someone is trying to remove the meter 200 from the service point, and in response, transmit a meter removal event to the central server 300. Each meter removal event will also have an associated timestamp indicating when the meter removal event was generated and/or transmitted. The meter application 220 can further detect and transmit a power outage event to the central server 300. The meter application 220 can receive data from the power sensor 210 to determine that the meter 200 is not currently receiving power from its power source, and in response, transmit a power outage event to the central server 300. Each power outage event will also have an associated timestamp indicating when the power outage event was generated and/or transmitted.

The meter application 220 also periodically generates and transmits transformer beacons 226 to the central server 300 that indicate which transformer of the utility network system (via a transformer ID) to which the meter 200 is currently connected. The meter application 220 can determine which transformer the meter 200 is currently connected using a transformer identification technique that implements a “Locational Awareness” feature. The Locational Awareness feature uses the strength of power-line carrier (PLC) messages and phase shift between the meters 200 to create groups of meters (transformer groups) that are currently connected to the same transformer. Each transformer group is assigned a unique transformer group ID. The Locational Awareness feature enables meters 200 on the utility network system to communicate with each other to ultimately figure out which transformer each meter 200 is currently connected. The transformer identification technique is also described in U.S. Pat. No. 9,835,662, entitled “Electrical Network Topology Determination,” by Driscoll et al., the contents of which are hereby incorporated by reference. The transformer identification technique is further described in U.S. Pat. No. 10,459,016, entitled “Electrical Network Topology Determination,” by Driscoll et al., the contents of which are hereby incorporated by reference. Notably, when a meter 200 is moved and coupled to a new transformer, the transformer beacon 226 will specify the transformer ID of the new transformer to which the meter 200 is currently connected.

### Central Server

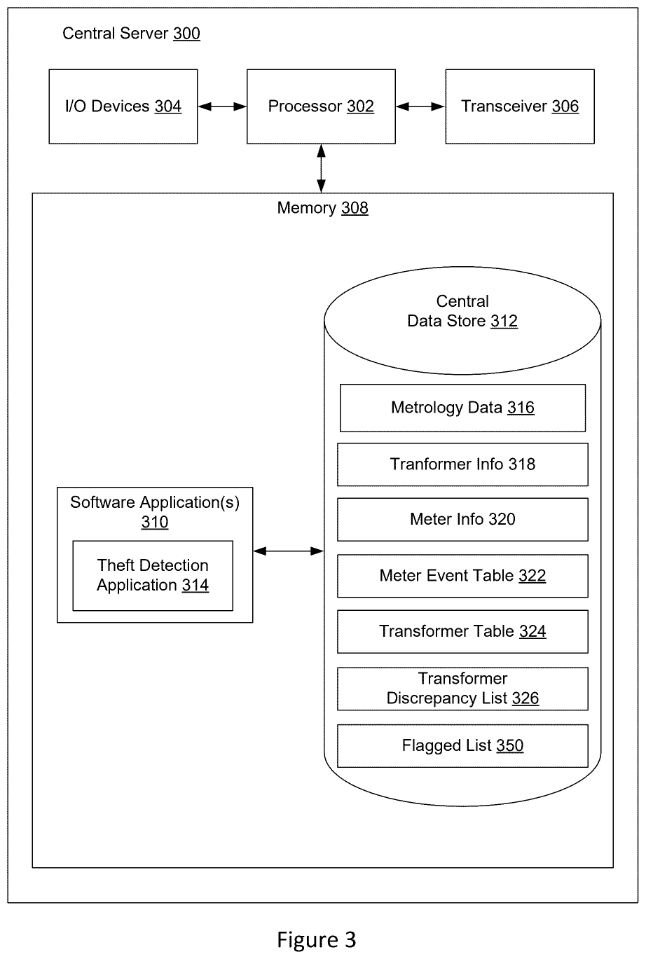

FIG. 3 illustrates central server 300, according to various embodiments. In some embodiments, the central server 300 is implemented as any type of computing device, such as a headend device, a backend server, or some other computing device or computer system, located at a central office or other facility of a utility provider, or a third-party service associated with detecting stolen meters. As shown, central server 300 includes, without limitation, processor 302, I/O devices 304, transceiver 306, and memory 308, coupled together via a bus.

Processor 302 coordinates operations of central server 300. In various embodiments, processor 302 includes any hardware configured to process data and execute software applications. The processor 302 can be any technically feasible processing device configured to process data and execute program instructions. For example, processor 302 could include one or more CPUs, DSPs, GPUs, ASICs, FPGAs, microprocessors, microcontrollers, other types of processing units, and/or a combination of different processing units. Processor 302 can include an RTC (not shown) according to which processor 302 maintains an estimate of the current time. The estimate of the current time can be expressed in UTC, although any other standard of time measurement can also be used.

I/O devices 304 include devices configured to receive input, devices configured to provide output, and devices configured to both receive input and provide output. Transceiver 306 is configured to transmit messages and/or receive data and/or other messages (such as meter events and transformer beacons) from devices, such as first meter 101A, second meter 102A, meters 200, and/or other devices associated with utility service providers, or a third-party service associated with detecting stolen meters.

Memory 308 includes one or more software applications 310 and a central data store 312, coupled together. As shown, the one or more software applications 310 include theft detection application 314. Central data store 312 stores metrology data 316, transformer information 318, meter information 320, meter event table 322, transformer table 324, transformer discrepancy list 326, and flagged list 350. Metrology data 316 includes, metrology data indicative of consumption of a utility commodity by a plurality of meters 200 of the utility network system.

Transformer information 318 includes information describing a plurality of transformers of the utility network system. For each transformer in the utility network system, the transformer information 318 can include a transformer ID and a location of the transformer. The transformer ID uniquely identifies the transformer within the utility network system. In some embodiments, the location of a transformer is specified by the latitude and longitude coordinates of the transformer.

Meter information 320 includes information describing a plurality of meters 200 of the utility network system. For each meter 200 in the utility network system, the meter information 320 can include a meter ID, an assigned transformer ID, and a location of the meter 200. The meter ID uniquely identifies the meter within the utility network system, The assigned transformer ID identifies a transformer within the utility network system that is initially assigned to the meter 200 by the central server 300. In some embodiments, the location of a meter 200 includes an address of a service point associated with the meter 200, such as a house or building to which the meter 200 is assigned by the central server 300. In other embodiments, the location of a meter 200 includes current GPS coordinates of the meter 200.

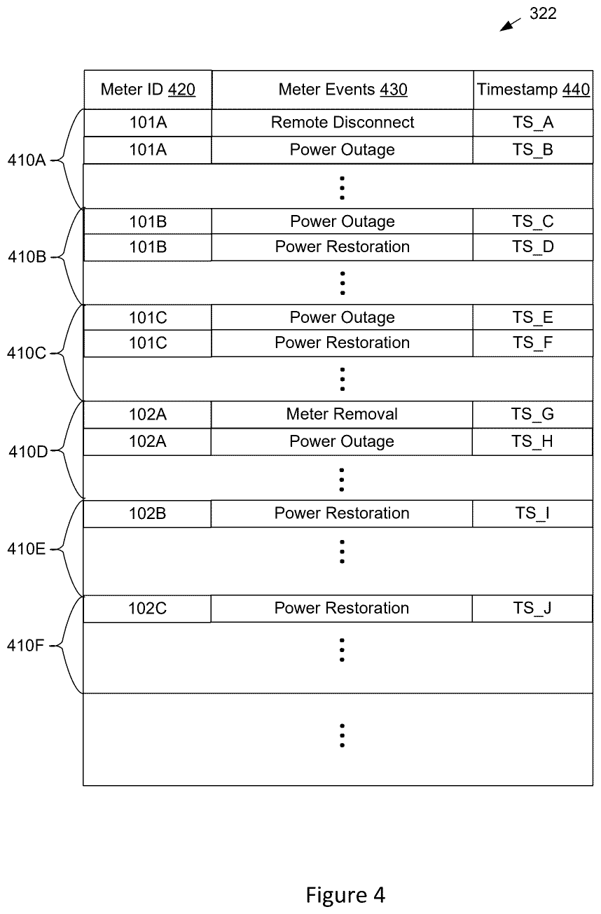

The meter event table 322 stores various meter events received from the plurality of meters 200 of the utility network system. FIG. 4 illustrates a conceptual diagram of the meter event table 322 of FIG. 3, according to various embodiments. As shown in FIG. 4, the meter event table 322 includes a plurality of sections 410 (such as 410A, 410B, 410C, etc.), each section 410 corresponding to a particular meter 200. Each section 410 includes a plurality of entries for the corresponding meter 200, each entry representing a meter event received from the meter 200. Each entry includes a meter ID 420, a meter event 430, and a timestamp 440. The meter ID 420 indicates the meter 200 that transmitted the meter event. The meter event 430 specifies the type of meter event that is received, such as a remote disconnect event, a power outage event, a meter removal event, and the like. The timestamp 440 indicates the day/time when the corresponding meter event was generated and transmitted by the meter 200, or the day/time when the corresponding meter event was received by the central server 300.

Note that for illustrative purposes only in the examples described herein, the last number of the meter ID for a particular meter 200 indicates the assigned transformer ID of the transformer that is initially assigned to the particular meter 200. For example, the meter ID “101A” for a first meter 101A indicates that the assigned transformer ID for the first meter 101A is “Tx1,” whereas the meter ID “102A” for a second meter 102A indicates that the assigned transformer ID for the second meter 102A is “Tx2.” For example, three meters assigned to transformer “Tx1” can have meter IDs “101A,” “101B,” and “101C.” For example, three meters assigned to transformer “Tx2” can have meter IDs “102A,” “102B,” and “102C.”

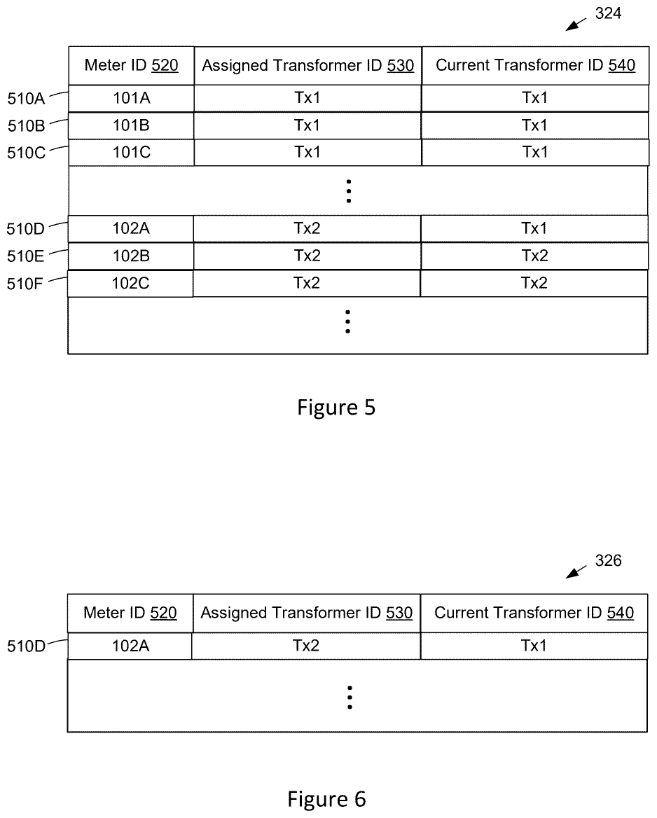

The transformer table 324 stores assigned transformer IDs and current transformer IDs associated with the plurality of meters 200 of the utility network system. FIG. 5 illustrates a conceptual diagram of the transformer table 324 of FIG. 3, according to various embodiments. As shown in FIG. 5, the transformer table 324 includes a plurality of entries 510 (such as 510A, 510B, 510C, etc.), each entry 510 corresponding to a particular meter 200. Each entry 510 specifies, for a corresponding meter 200, a meter ID 520, an assigned transformer ID 530, and a current transformer ID 540. The assigned transformer ID 530 identifies the transformer within the utility network system that is initially assigned to the corresponding meter 200 by the central server 300. The current transformer ID 540 identifies the transformer within the utility network system to which the corresponding meter 200 is currently connected. The current transformer ID 540 is received from the corresponding meter 200 via the transformer beacons 226 and then stored to the transformer table 324 in the entry 510 for the corresponding meter 200. In normal operation (when no meters have been stolen and illicitly installed), the current transformer ID 540 should match the assigned transformer ID 530 for each meter 200.

The theft detection application 314 routinely analyzes the transformer table 324 to identify entries 510 having a discrepancy/mismatch between the assigned transformer ID 530 and the current transformer ID 540 (i.e., the assigned transformer ID 530 does not equal the current transformer ID 540), referred to herein as discrepant entries 510. The theft detection application 314 then adds any discrepant entries 510 of the transformer table 324 to the transformer discrepancy list 326. FIG. 6 illustrates a conceptual diagram of the transformer discrepancy list 326 of FIG. 3, according to various embodiments. The transformer discrepancy list 326 includes the discrepant entries 510 from the transformer table 324 of FIG. 5. In the example of FIG. 6, the transformer discrepancy list 326 includes the discrepant entries 510D corresponding to the second meter 102A that has an assigned transformer ID of Tx2 and a current transformer ID of Tx1, indicating that the second meter 102A has been removed/disconnected from transformer Tx2 and is currently connected to transformer Tx1. In other embodiments, the theft detection application 314 does not maintain a separate transformer discrepancy list 326, but rather flags the discrepant entries 510 within the transformer table 324.

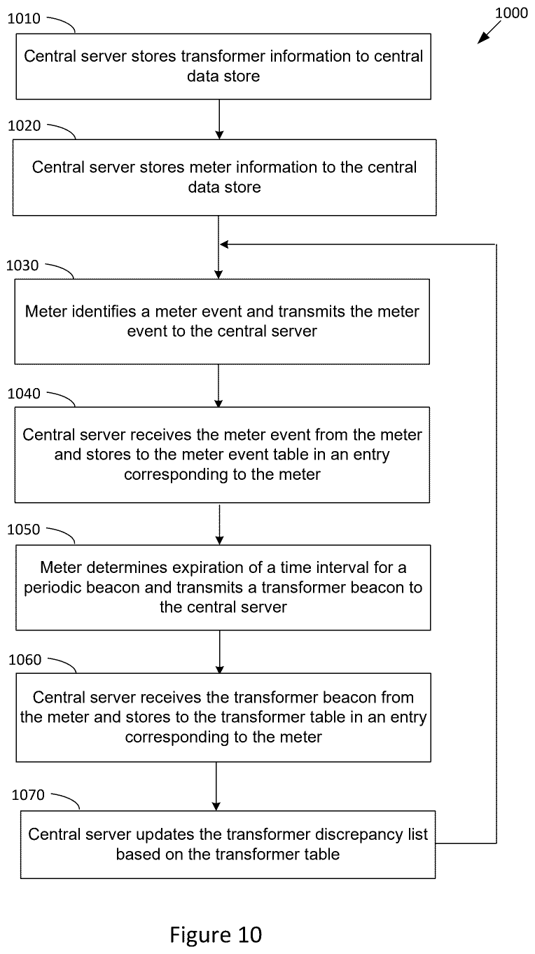

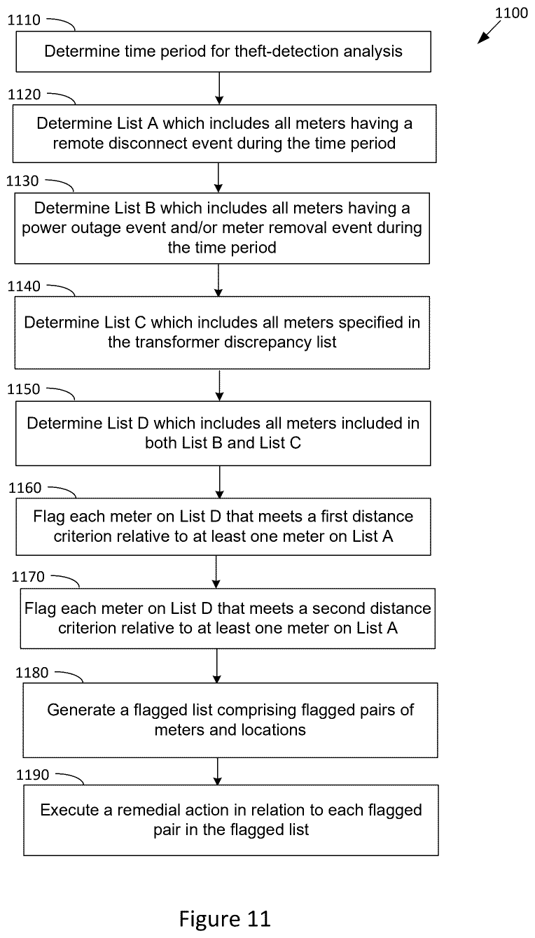

When executed by processor 302, theft detection application 314 collects the various information 318-326 in the central data store 312, discussed below in relation to FIG. 10, and executes a theft-detection algorithm, discussed below in relation to FIG. 11, to generate the flagged list 350 based on the collected information 318-326. The flagged list 350 identifies/flags potential stolen meters and likely locations of the stolen meters (referred to herein as flagged meters and flagged locations) based on the collected information 318-326. The theft detection application 314 can then perform a remedial action in relation to each flagged meter on the flagged list 350, such as generating a work order for a utility worker to inspect a flagged meter at a flagged location to verify if the flagged meter is a stolen meter or perform other actions.

In general, the theft-detection algorithm determines a time period to perform an analysis and determines “List A” which includes meters 200 that had a remote disconnect event during the time period. The theft-detection algorithm then determines “List B” which includes meters 200 that had a power outage event and/or meter removal event during the time period. The theft-detection algorithm then determines “List C” which includes meters 200 specified in the transformer discrepancy list 326. The theft-detection algorithm then determines “List D” which includes meters 200 that are included in both List B and List C. Thus, each meter 200 on List D could be a meter 200 that has been removed from its assigned service point (as indicated by List B) and has been installed to a different service point (as indicated by List C). Therefore, there is a reasonable level of confidence at this point that each meter 200 on List D is a stolen meter and can be flagged as such.

However, in some embodiments, the theft-detection algorithm includes one or more double-checking steps that can be implemented separately or in combination to increase the confidence that the flagged meters are in fact stolen meters. In particular, the theft-detection algorithm can identify each meter 200 on List D that meets/satisfies one or more distance criteria relative to at least one location on a list of locations associated with List A, and flags/identifies each meter 200 satisfying the one or more distance criteria as a potential stolen meter and flags/identifies the at least one location as a potential location where the stolen meter is currently being used.

Each meter 200 on List A is associated with at least one location, such as the location of the assigned transformer or the assigned service point for the meter 200. In general, the location of the assigned transformer and/or assigned service point for a remote disconnected meter is a more likely location where a stolen meter will be illicitly installed and used. In some embodiments, the theft detection algorithm flags/identifies each meter 200 on List D that a first distance criterion relative to at least one location on the list of locations associated with List A, wherein the at least one location is also flagged. The first distance criterion is based on the assumption that a customer that is stealing a meter will steal the meter from a relatively short distance (such as less than a few miles) from the customer's service point and within a threshold distance from the customer's service point. The theft detection algorithm can do so by identifying a first meter from List A and a first location associated with the first meter from the list of locations associated with List A. The theft detection algorithm will also identify a second meter from List D and a second location associated with the second meter. The theft detection algorithm will then determine if the second location is within the threshold distance from the first location. If so, the theft detection algorithm determines that the second meter satisfies the first distance criterion, and in response, flags/identifies the second meter as a potential stolen meter and flags/identifies the first location as a potential location where the second meter is currently being used.

In other embodiments, the theft detection algorithm flags/identifies each meter 200 on List D that meets/satisfies a second distance criterion relative to at least one meter 200 on List A. To do so, the theft detection algorithm can identify a first meter from List A and a first location associated with the first meter from the list of locations associated with List A. The first location comprises the location of the assigned first transformer for the first meter. The theft detection algorithm will also identify a second meter from List D and a second location associated with the second meter. The second location comprises the location of the currently connected transformer for the second meter. The theft detection algorithm will then determine if the distance between the first location and the second location is 0. If so, the second meter is flagged as a potential stolen meter and the first location is flagged as a potential location where the second meter is currently being used.

### Detecting Stolen Meters

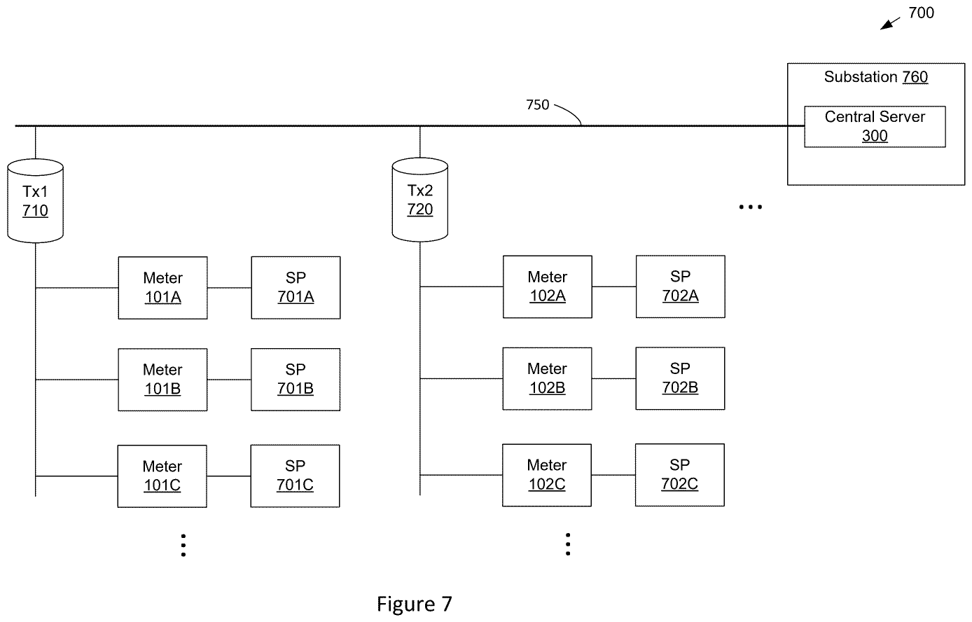

FIG. 7 illustrates a block diagram of a commodity distribution system 700 during a first stage of operation of the utility network system, according to various embodiments. The first stage of operation of the utility network system is during normal operation when no meters have been stolen from an assigned service point and illicitly installed at another service point in the utility network system.

As shown, the stolen meter detection system 700 includes a first transformer Tx1 710, a first set of meters 101 (such as 101A, 101B, and 101C) that are currently coupled/connected to the first transformer Tx1 710, a second transformer Tx2 720, a second set of meters 102 (such as 102A, 102B, and 102C) that are currently coupled/connected to the second transformer Tx2 720, and a central server 300 that are connected to each other by a communication medium 750, such as a wired or wireless connection. The central server 300 can be located in a substation//utility 760. In other embodiments, the central server 300 can be a cloud-based server at a different location. Each meter 101, 102 is assigned to a particular service point (“SP”), such as a house or other premises, by the central server 300. For example, meter 101A is assigned to service point (SP) 701A, meter 102A is assigned to service point (SP) 702A, and so forth.

Each meter in the first set of meters 101 has been initially assigned to the first transformer Tx1 710 and each meter in the second set of meters 102 has been initially assigned to the second transformer Tx2 720 by the central server 300. Therefore, each meter 101, 102 is currently connected to the transformer that is the same transformer as the transformer initially assigned by the central server 300. As such, for the example of FIG. 7 in the first stage of operation, the transformer table 324 would not include any discrepant entries 510 having a discrepancy/mismatch between the assigned transformer ID 530 and the current transformer ID 540 for any meter.

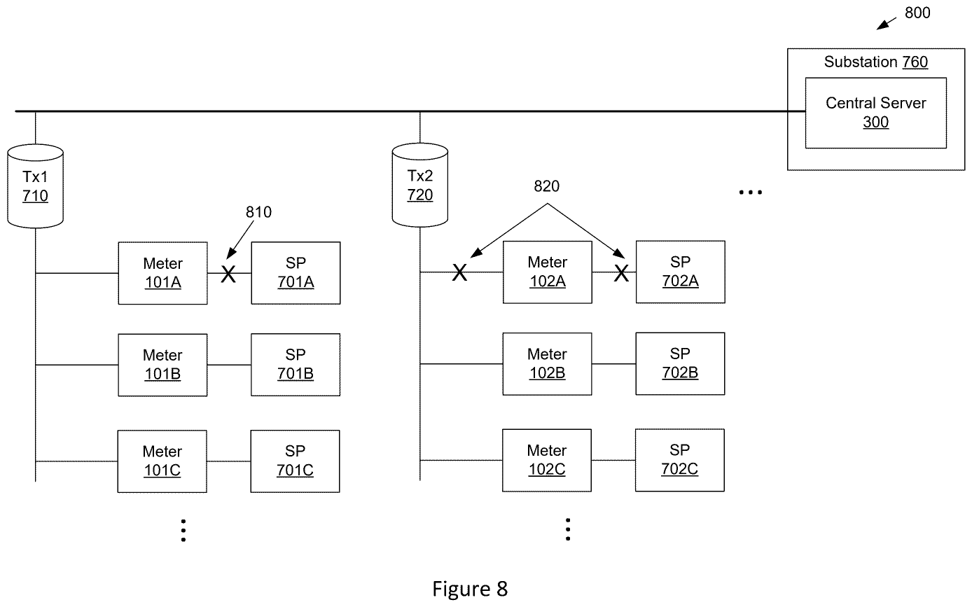

FIG. 8 illustrates a block diagram of a commodity distribution system 800 during a second stage of operation of the utility network system, according to various embodiments. In the second stage of operation of the utility network system, one meter in the utility network system is remotely disconnected from its assigned service point and another meter in the utility network system is physically stolen/removed from its assigned service point. The second stage of operation shown in FIG. 8 follows the first stage of operation shown in FIG. 7.

As shown, a first meter 101A is remotely disconnected from the assigned first service point 701A at action 810. For example, a first customer at the first service point 701A may be delinquent on bill payments, and in response, the central server 300 has sent a remote disconnect command to the first meter 101A. In response, the first meter 101A executes the remote disconnect command and transmits a remote disconnect event to the central server 300. The central server 300 stores the remote disconnect event to the meter event table 322 in an entry corresponding to the first meter 101A. When the first meter 101A is remote disconnected, the first meter 101A is effectively disabled from providing electricity to any service point, as indicated by action 810.

In general, an assigned transformer and/or assigned service point associated with a remote disconnected meter is a more likely location where a stolen meter will be illicitly used and installed relative to an assigned transformer and/or assigned service point that is not associated with a remote disconnected meter. For example, transformer Tx1 710 and/or first service point 701A associated with the first meter 101A is a more likely location where a stolen meter will be illicitly installed relative to, for example, transformer Tx2 720 and/or service point 702C associated with meter 102C that has not been remotely disconnected. The first customer associated with the first meter 101A has a motive to steal another meter and illicitly use and install the stolen meter at transformer Tx1 710 and the first service point 701A, whereas the customer associated with meter 102C does not have motive to steal another meter and illicitly use ad install the stolen meter.

As also shown in FIG. 8, a second meter 102A has been physically stolen/removed from an assigned second service point 702A at action 820. When the second meter 102A is removed from the socket, the second meter 102A will detect and transmit a power outage event and/or a meter removal event to the central server 300. The central server 300 stores the power outage event and/or a meter removal event to the meter event table 322 in one or more entries corresponding to the second meter 102A.

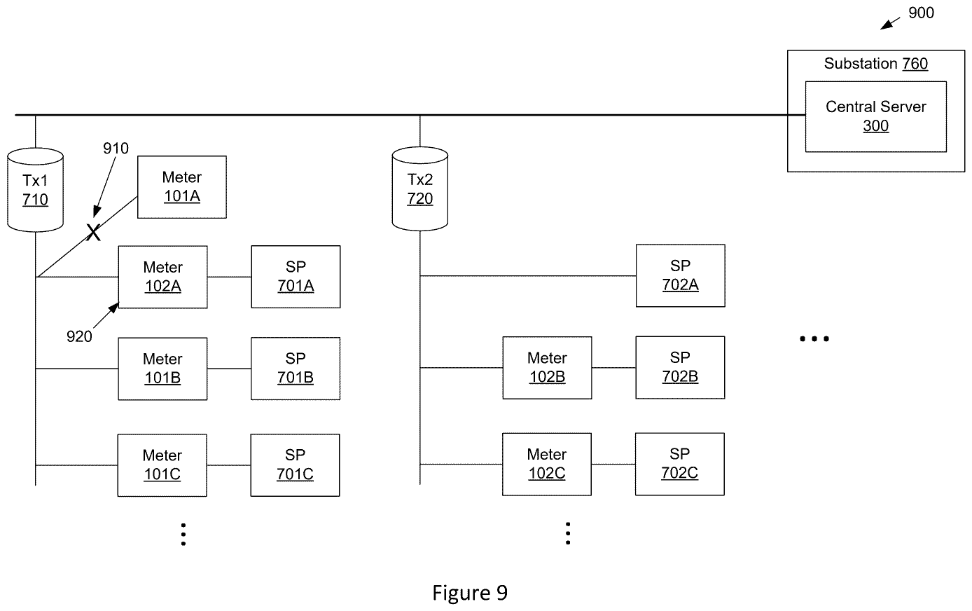

FIG. 9 illustrates a block diagram of a commodity distribution system 900 during a third stage of operation of the utility network system, according to various embodiments. In the third stage of operation of the utility network system, a stolen meter is illicitly installed at a service point in the utility network system. The third stage of operation shown in FIG. 9 follows the second stage of operation shown in FIG. 8.

As shown, the first meter 101A has been physically removed from the assigned first service point 701A at action 910. When the first meter 101A is removed from the socket, the first meter 101A will detect and transmit a power outage event and/or a meter removal event to the central server 300. The central server 300 stores the power outage event and/or a meter removal event to the meter event table 322 in one or more entries corresponding to the first meter 101A.

As also shown in FIG. 9, the second meter 102A has been physically installed at the first service point 701A and is being used to provide a utility commodity to the first service point 701A at action 920. Since the second meter 102A has not been remotely disconnected/disabled, the second meter 102A is still able to provide a utility commodity to a connected service point. For providing an electricity commodity, the second meter 102A is still capable of providing electricity to a load (service point). However, when the second meter 102A sends a next periodic transformer beacon 126 to the central server 300, the transformer beacon 126 specifies that the second meter 102A is currently connected to the first transformer Tx1 710. The central server 300 retrieves and updates the entry 510D corresponding to the second meter 102A from the transformer table 324. In particular, the central server 300 stores “Tx1” as the current transformer ID 540 for the second meter 102A in the corresponding entry 510D. As shown in the example of FIG. 5, the corresponding entry 510D is a discrepant entry 510 since there is now a mismatch between the assigned transformer ID 530 (“Tx2”) and the current transformer ID 540 (“Tx1”). Thus, as shown in the example of FIG. 6, the corresponding entry 510D for the second meter 102A is added to the transformer discrepancy list 326.

In the example situations shown in FIGS. 7-9, the second meter 102A is a stolen meter that has been physically removed from the second service point 702A and is currently installed and being used at the first service point 701A to provide a utility commodity to the first service point 701A. As described below in relation to FIGS. 10-11, using the collected information 318-326 stored to the central data store 312, theft detection application 314 executes a theft-detection algorithm that will flag the second meter 102A as a stolen meter and flag the first service point 701A as the current location of the stolen meter. Thus, the flagged list 350 will include the second meter 102A as a flagged meter and the first service point 701A as a flagged location.

FIG. 10 is a flow diagram of method steps for an information collection phase, according to various embodiments. In some embodiments, a method 1000 can be performed by a plurality of meters 200 (such as first meter 101A and second meter 102A) in conjunction with the central server 300 of a utility network system. The various steps performed by a meter 200 described herein can be performed, for example, by the meter application 220 executing on the meter 200. The various steps performed by the central server 300 described herein can be performed, for example, by the theft detection application 314 executing on the central server 300. The information collection phase is performed to collect and store various information 318-326 to the central data store 312 of the central server 300 for later use in a theft-detection algorithm discussed below in relation to FIG. 11. Although the method steps are shown in an order, persons skilled in the art will understand that some method steps may be performed in a different order, repeated, and/or performed by components other than those described in FIG. 10.

As shown, the method 1000 begins at step 1010, where the central server 300 stores transformer information 318 to the central data store 312. Transformer information 318 can include, for each transformer in the utility network system, a transformer ID and a location of the transformer. At step 1020, the central server 300 stores meter information 320 to the central data store 312. Meter information 320 can include, for each meter in the utility network system, a meter ID, an assigned transformer ID, and a location of the meter 200.

At step 1030, a particular meter 200 identifies a meter event 124 occurring at the meter 200 and transmits a message that specifies the meter event 124 to the central server 300. The particular meter 200 can be any meter 200 within the utility network system. For example, a meter event 124 can include, without limitation, a remote disconnect event, a power outage event, and a meter removal event. At step 1040, the central server 300 receives the meter event 124 from the particular meter 200 and stores the meter event 124 to the meter event table 322 in an entry corresponding to the particular meter 200. The corresponding entry includes data fields specifying the meter event 124 including, without limitation, a meter ID 420, the type of meter event 430, and an associated timestamp 440.

At step 1050, a particular meter 200 determines that a time interval for a periodic transformer beacon 126 has expired, and in response generates and transmits a transformer beacon 126 to the central server 300. The particular meter 200 can be any meter 200 within the utility network system. The transformer beacon 126 specifies the transformer ID of a transformer to which the particular meter 200 is currently connected. At step 1060, the central server 300 receives the transformer beacon 126 from the particular meter 200 and stores the transformer beacon 126 to the transformer table 324 in an entry 510 corresponding to the particular meter 200. The corresponding entry 510 includes data fields including, without limitation, a meter ID 520, an assigned transformer ID 530, and a current transformer ID 540. At step 1070, in response to updating the transformer table 324 at step 1060, the central server 300 also updates the transformer discrepancy list 326 by identifying any discrepant entries 510 in the transformer table 324 and adding the discrepant entries 510 to the transformer discrepancy list 326.

Then method 1000 then indefinitely repeats at step 1030. In this manner, a plurality of meters 200 within the utility network system can continually generate and transmit meter events 124 and transformer beacons 126 to the central server 300. In this manner, the central server 300 can also continually receive the meter events 124 and transformer beacons 126 from the plurality of meters 200, store the meter events 124 to the meter event table 322, and store the transformer beacons 126 to the transformer table 324, while also continually updating the transformer discrepancy list 326 based on the updated transformer table 324.

FIG. 11 is a flow diagram of method steps for executing a theft-detection algorithm, according to various embodiments. In some embodiments, the theft-detection algorithm can be executed by the theft detection application 314 executing on the central server 300 of a utility network system. The theft-detection algorithm can be executed by the theft detection application 314 to generate a flagged list 350 of flagged meters and flagged locations based on the information 318-326 collected and stored to the central data store 312 during the information collection phase discussed in relation to FIG. 10. Although the method steps are shown in an order, persons skilled in the art will understand that some method steps may be performed in a different order, repeated, and/or performed by components other than those described in FIG. 11.

As shown, a method 1100 begins at step 1110, where the theft detection application 314 determines a time period/range (such as a range of days) to perform an analysis for the theft-detection algorithm. For example, the theft detection application 314 can receive a specified time period from an administrator of the central server 300 or other personnel of the utility provider.

At step 1120, the theft detection application 314 determines (computes/generates) “List A” which includes all meters 200 in the utility network system that had a remote disconnect event during the time period. The theft detection application 314 can determine List A by analyzing the meter event table 322 to identify all meters 200 that transmitted a remote disconnect event during the time period. In particular, the theft detection application 314 can identify each matching entry in the meter event table 322 having both a type of meter event 430 comprising a remote disconnect event and an associated timestamp 440 that is within the time period. For each such matching entry in the meter event table 322, the meter ID 420 can be added to List A. In the example of FIG. 8, the first meter 101A transmits a remote disconnect event at action 810 and would be added to List A, assuming that the associated timestamp 440 is within the time period.

In steps 1130-1150 described below, the theft detection application 314 identifies meters 200 having one or more characteristics/properties of a stolen meter, such as a first, second, and/or third characteristics/properties of a stolen meter. At step 1130, the theft detection application 314 determines “List B” which includes all meters 200 in the utility network system that had a power outage event and/or meter removal event during the time period. The theft detection application 314 can determine List B by analyzing the meter event table 322 to identify all meters 200 that transmitted a power outage event and/or meter removal event during the time period. In particular, the theft detection application 314 can identify each matching entry in the meter event table 322 having both a type of meter event 430 comprising a power outage event or a meter removal event and an associated timestamp 440 that is within the time period. For each such matching entry in the meter event table 322, the meter ID 420 can be added to List B. Each meter 200 on List B is a meter that could have been physically and illicitly removed from its socket at the assigned service point, which triggered a power outage event and/or meter removal event at the meter 200. Thus, a particular meter 200 being included in List B identifies the meter 200 at having a first characteristic/property of a stolen meter.

In the example of FIG. 8, the second meter 102A transmits a power outage event and/or meter removal event at action 820 and would be added to List B, assuming that the associated timestamp 440 is within the time period. Thus, since the second meter 102A is included in List B, the second meter 102A is identified as having a first characteristic of a stolen meter. In the example of FIG. 9, the first meter 101A transmits a power outage event and/or meter removal event at action 910 and would be added to List B, assuming that the associated timestamp 440 is within the time period. Thus, since the first meter 101A is included in List B, the first meter 101A is identified as having a first characteristic of a stolen meter.

At step 1140, the theft detection application 314 determines “List C” which comprises all the meters 200 specified in the transformer discrepancy list 326. The theft detection application 314 can determine List C by retrieving the transformer discrepancy list 326 from the central data store 312. Each meter 200 on List C is a meter 200 having a discrepancy/mismatch between the assigned transformer ID 530 and the current transformer ID 540. Thus, a meter 200 on List C can be a meter 200 that has been physically and illicitly removed from a service point connected to the initially assigned transformer and then physically and illicitly installed at another service point connected to a different transformer. Thus, a particular meter 200 being included in List C identifies the meter 200 at having a second characteristic of a stolen meter.

In the examples of FIGS. 8-9, the second meter 102A is specified in the transformer discrepancy list 326 and would be added to List C due to the mismatch between the assigned transformer ID 530 (“Tx2”) and the current transformer ID 540 (“Tx1”). Thus, since the second meter 102A is included in List C, the second meter 102A is identified as having a second characteristic of a stolen meter. In the examples of FIGS. 8-9, the second meter 102A has been removed from service point 702A connected to the assigned transformer ID 530 (“Tx2”) and then installed at service point 701A connected to the current transformer ID 540 (“Tx1”).

At step 1150, the theft detection application 314 determines “List D” which comprises all meters 200 that are included in both List B and List C (i.e., comprises the meter overlap between List B and List C). As such, each meter 200 on List D is a meter 200 that has had a power outage event or meter removal event during the time period and has a mismatch between the assigned transformer ID 530 and the current transformer ID 540. Thus, each meter 200 on List D could be a meter 200 that has been removed from its assigned service point (as indicated by List B) and has been installed to a different service point (as indicated by List C). Therefore, there is a reasonable level of confidence at this point that each meter 200 on List D is a stolen meter and can be flagged as such. Thus, a particular meter 200 being included in List D identifies the meter 200 at having a third characteristic of a stolen meter.

However, in some embodiments, the theft-detection algorithm includes one or more double-checking steps (discussed below in relation to steps 1160 and 1170) that can be implemented separately or in combination to increase the confidence that the flagged meters are in fact stolen meters. At steps 1160 and 1170, the theft detection application 314 identifies each meter 200 on List D that meets/satisfies one or more distance criteria relative to at least one meter 200 on List A. In particular, at steps 1160 and 1170, the theft detection application 314 identifies each meter 200 on List D that meets/satisfies one or more distance criteria relative to at least one location on a list of locations associated with List A, and flags/identifies each meter 200 satisfying the one or more distance criteria as a potential stolen meter and flags/identifies the at least one location as a potential location where the stolen meter is currently being used.

Each meter 200 on List A is associated with at least one location. For example, the location associated with the meter 200 can comprise the location of the assigned transformer for the meter 200. For example, the location associated with the meter 200 can comprise a location of the assigned service point for the meter 200, such as an address of a house or building assigned to the meter 200. In other embodiments, the location associated with the meter 200 comprises current GPS coordinates of the meter 200. In general, the location of the assigned transformer and/or assigned service point for a remote disconnected meter is a more likely location where a stolen meter will be illicitly installed relative to a transformer and/or service point that is not associated with a remote disconnected meter. For example, transformer Tx1 710 and/or first service point 701A associated with the first meter 101A is a more likely location where a stolen meter will be illicitly installed relative to, for example, transformer Tx2 720 and/or service point 702C associated with meter 102C that has not been remotely disconnected. Thus, List A is associated with a list of locations where a stolen meter is likely to be used, whereby each meter 200 on List A is associated with at least one location where a stolen meter is likely to be used.

At step 1160, the theft detection application 314 flags/identifies each meter 200 on List D that meets/satisfies a first distance criterion relative to at least one meter 200 on List A. To do so, the theft detection application 314 can analyze each meter 200 on List D against each meter 200 on List A. In particular, at step 1160, the theft detection application 314 flags/identifies each meter 200 on List D that meets/satisfies a first distance criterion relative to at least one location on the list of locations associated with List A, wherein the at least one location is also flagged. The first distance criterion is based on the assumption that a customer that is stealing a meter will steal the meter from a relatively short distance (such as less than a few miles) from the customer's service point and within a predetermined threshold distance from the customer's service point.

To perform step 1160, the theft detection application 314 will identify a first meter from List A and a first location associated with the first meter from the list of locations associated with List A. For example, the first location can comprise the location of the assigned transformer or the location of the assigned service point for the first meter. The theft detection application 314 will also identify a second meter from List D and a second location associated with the second meter. For example, the second location can comprise the location of the assigned transformer or the location of the assigned service point for the second meter. The theft detection application 314 will then determine if the second location is within a predetermined threshold distance from the first location. If so, the theft detection application 314 determines that the second meter satisfies the first distance criterion, and in response, flags/identifies the second meter as a potential stolen meter and flags/identifies the first location as a potential location where the second meter is currently being used.

To determine whether the second location is within the predetermined threshold distance from the first location, the theft detection application 314 can use the any combination of the different types of locations for the first and second locations. For example, the first location can comprise the assigned first transformer for the first meter and the second location can comprise the assigned second transformer for the second meter, whereby the latitude and longitude coordinates of the assigned first and second transformers are used to determine the distance between the first and second locations. For example, the first location can comprise the assigned first service point for the first meter and the second location can comprise the assigned second service point for the second meter, whereby the addresses of the assigned first and second service points are used to determine the distance between the first and second locations. For example, the first location can comprise the assigned first service point for the first meter and the second location can comprise the assigned second transformer for the second meter, whereby the address of the assigned first service point and the latitude and longitude coordinates of the second transformer are used to determine the distance between the first and second locations. For example, the first location can comprise the assigned first transformer for the first meter and the second location can comprise the assigned second service point for the second meter, whereby the latitude and longitude coordinates of the first transformer and the address of the second service point are used to determine the distance between the first and second locations.

At step 1160, in the examples of FIGS. 8-9, the theft detection application 314 identifies first meter 101A from List A having an associated first location comprising assigned first transformer Tx1 710 or assigned first service point 701A. The theft detection application 314 also identifies second meter 102A from List D having an associated second location comprising assigned second transformer Tx2 720 or assigned second service point 702A. If the theft detection application 314 determines that the second location is within the predetermined threshold distance from the first location (thus meeting the first distance criterion), then the second meter 702A is flagged as a potential stolen meter and the first location (first transformer Tx1 710 and/or first service point 701A) is flagged as a potential location where the second meter 702A is currently being used.

At step 1170, the theft detection application 314 flags/identifies each meter 200 on List D that meets/satisfies a second distance criterion relative to at least one meter 200 on List A. To do so, the theft detection application 314 can analyze each meter 200 on List D against each meter 200 on List A. In particular, at step 1170, the theft detection application 314 flags/identifies each meter 200 on List D that meets/satisfies a second distance criterion relative to at least one location on the list of locations associated with List A, wherein the at least one location is also flagged. The second distance criterion is based on the locations of two associated transformers that match/overlap, thus whereby a distance between the two associated transformers equal to 0.

To perform step 1170, the theft detection application 314 will identify a first meter from List A and a first location associated with the first meter from the list of locations associated with List A. The first location comprises the location of the assigned first transformer for the first meter. The theft detection application 314 will also identify a second meter from List D and a second location associated with the second meter. The second location comprises the location of the currently connected transformer for the second meter. The theft detection application 314 will then determine if the distance between the first location and the second location is 0. The theft detection application 314 can do so by using the latitude and longitude coordinates of the assigned first transformer for the first meter and the currently connected transformer for the second meter to determine the distance between the two transformers. In other embodiments, the theft detection application 314 can do so by determining if the transformer ID of the assigned first transformer for the first meter matches the transformer ID for the currently connected transformer for the second meter, and if so, determines that the distance between the first location and the second location is 0. If the distance between the first location and the second location is determined to equal 0, the theft detection application 314 determines that the second meter satisfies the second distance criterion, and in response, flags/identifies the second meter as a potential stolen meter and flags/identifies the first location as a potential location where the second meter is currently being used.

At step 1170, in the example of FIG. 8, the theft detection application 314 identifies first meter 101A from List A having an associated first location comprising the assigned first transformer Tx1 710. The theft detection application 314 also identifies second meter 102A from List D having an associated second location comprising the currently connected first transformer Tx1 710. Therefore, the theft detection application 314 determines that the first and second locations have a distance equal to 0 (thus meeting the second distance criterion), whereby the second meter 702A is flagged as a potential stolen meter and the first location (first transformer Tx1 710 and/or first service point 701A) is flagged as a potential location where the second meter 702A is currently being used.

At step 1180, the theft detection application 314 generates the flagged list 350 comprising flagged pairs of meters and locations. Each flagged pair specifies a potential stolen meter and a potential location where the stolen meter is currently being used. In some embodiments, each flagged pair in the flagged list 350 has satisfied the first distance criterion. In other embodiments, each flagged pair in the flagged list 350 has satisfied the second distance criterion. In further embodiments, each flagged pair in the flagged list 350 has satisfied both the first distance criterion and the second distance criterion.

At step 1190, for each flagged pair in the flagged list 350, the theft detection application 314 executes a remedial action in relation to the flagged pair. In some embodiments, the remedial action includes causing an inspection of the flagged meter at the flagged location. In other embodiments, the remedial action includes generating a work order for a utility worker to inspect the flagged meter at the flagged location to verify if the flagged meter is a stolen meter, or to perform other actions. In further embodiments, the remedial action includes transmitting a remote disconnect command to the flagged meter at the flagged location to cause the flagged meter to remotely disconnect the flagged meter at the flagged location. The method 1100 then ends. Method 1100 can also be repeated for additional time periods.

### Utility Network System

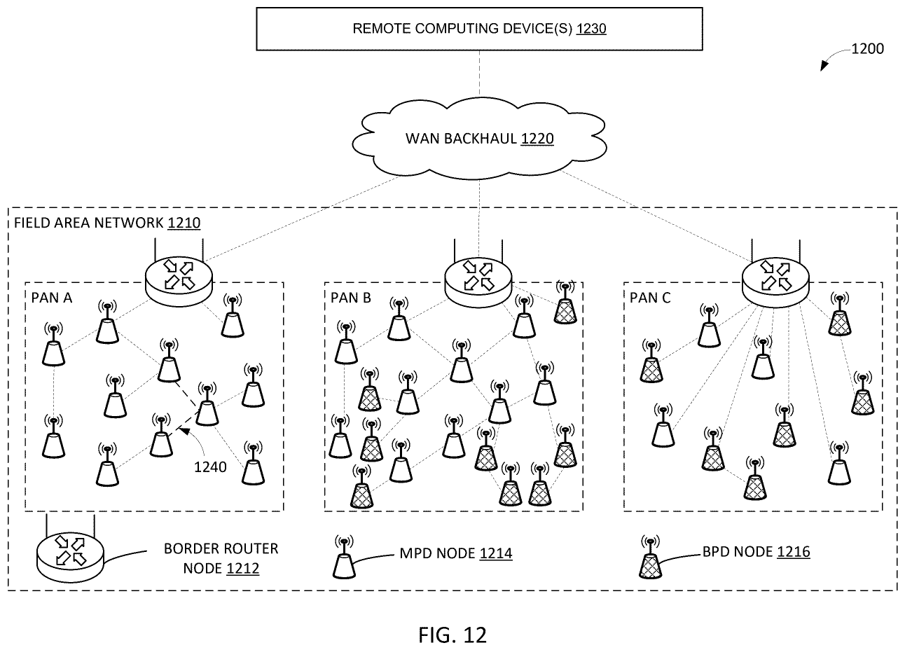

FIG. 12 illustrates a utility network system configured to implement one or more aspects of the various embodiments. As shown, utility network system 1200 includes a field area network (FAN) 1210, a wide area network (WAN) backhaul 1220, and one or more remote computing devices 1230 (such one or more central servers 300). FAN 1210 is coupled to remote computing device(s) 1230 via WAN backhaul 1220.

FAN 1210 includes personal area network (PANs) A, B, and C. PANs A and B are organized according to a mesh network topology, while PAN C is organized according to a star network topology. Each of PANs A, B, and C includes various network devices including at least one border router node 1212 and one or more mains-powered device (MPD) nodes 1214. PANs B and C further include one or more battery-powered device (BPD) nodes 1216. Any of the one or more MPD nodes 1214 or the BPD nodes 1216 can be used to implement the techniques discussed above with respect to FIGS. 1-11. In various embodiments, nodes 1214 or 1216 can be implemented as first meter 101A, second meter 102A, meter 200, and/or central server 300.

MPD nodes 1214 draw power from an external power source, such as mains electricity or a power grid. MPD nodes 1214 typically operate on a continuous basis without powering down for extended periods of time. BPD nodes 1216 draw power from an internal power source, such as a battery. BPD nodes 1216 typically operate intermittently and power down, go to very low power mode, for extended periods of time in order to conserve battery power.

MPD nodes 1214 and BPD nodes 1216 are coupled to, or included within, a utility distribution infrastructure (not shown) that distributes a resource to consumers. MPD nodes 1214 and BPD nodes 1216 gather sensor data related to the distribution of the resource, process the sensor data, and communicate processing results and other information to remote computing device(s) 1230. Border router nodes 1212 operate as access points to provide MPD nodes 1214 and BPD nodes 1216 with access to remote computing device(s) 1230.

Any of border router nodes 1212, MPD nodes 1214, and BPD nodes 1216 are configured to communicate directly with one or more adjacent nodes via bi-directional communication links 1240. The communication links 1240 may be wired or wireless links, although in practice, adjacent nodes of a given PAN exchange data with one another by transmitting data packets via wireless radio frequency (RF) communications. The various node types are configured to perform a technique known in the art as “channel hopping” in order to periodically receive data packets on varying channels. As known in the art, a “channel” may correspond to a particular range of frequencies. In one embodiment, a node may compute a current receive channel by evaluating a Jenkins hash function based on a total number of channels and the media access control (MAC) address of the node.

In some examples, MPD nodes 1214 or BPD nodes 1216 can communicate directly with remote computing devices 1230 via respective cellular communication links. In such examples, MPD nodes 1214 or BPD nodes 1216 can transmit messages to and/or receive messages from remote computing devices 1230 without using border router nodes 1212. Furthermore, in some examples, remote computing devices 1230 are implemented as MPD nodes 1214 or BPD nodes 1216. In such examples, MPD nodes 1214 and BPD nodes 1216 can perform the control and/or data analysis functions described herein with respect to remote computing devices 1230.

In some examples, each node within a given PAN can implement a discovery protocol to identify one or more adjacent nodes or “neighbors.” A node that has identified an adjacent, neighboring node can establish a bi-directional communication link 1240 with the neighboring node. Each neighboring node may update a respective neighbor table to include information concerning the other node, including one or more of the MAC address of the other node, listening schedule information for the other node, a received signal strength indication (RSSI) of the communication link 1240 established with that node, and the like.

Nodes can compute the channel hopping sequences of adjacent nodes to facilitate the successful transmission of data packets to those nodes. In embodiments where nodes implement the Jenkins hash function, a node computes a current receive channel of an adjacent node using the total number of channels, the MAC address of the adjacent node, and a time slot number assigned to a current time slot of the adjacent node.

Any of the nodes discussed above may operate as a source node, an intermediate node, or a destination node for the transmission of data packets. A given source node can generate a data packet and then transmit the data packet to a destination node via any number of intermediate nodes (in mesh network topologies). The data packet can indicate a destination for the packet and/or a particular sequence of intermediate nodes to traverse in order to reach the destination node. In one embodiment, each intermediate node can include a forwarding database indicating various network routes and cost metrics associated with each route.

Nodes can transmit messages and/or data packets across a given PAN and across WAN backhaul 1220 to remote computing device(s) 1230. Similarly, remote computing device(s) 1230 can transmit messages and/or data packets across WAN backhaul 1220 and across any given PAN to a particular node included therein. As a general matter, numerous routes can exist which traverse any of PANs A, B, and C and include any number of intermediate nodes, thereby allowing any given node or other component within network system 1200 to communicate with any other node or component included therein.

Remote computing device(s) 1230 includes one or more server machines (such one or more central servers 300) or other computing devices configured to operate as sources for, or destinations of, messages and/or data packets that traverse within network system 1200. The server machines can query nodes within network system 1200 to obtain various data, including raw or processed sensor data, power consumption data, node/network throughput data, status information, and so forth. The server machines can also transmit commands and/or program instructions to any node within network system 1200 to cause those nodes to perform various operations. In one embodiment, each server machine is a computing device configured to execute, via a processor, a software application stored in a memory to perform various network management and/or theft detection operations. In various embodiments, central server 300 is implemented as a remote computing device 1230.

In sum, the theft-detection algorithm determines a time period to perform an analysis and determines “List A” which includes meters 200 that had a remote disconnect event during the time period. The theft-detection algorithm then determines “List B” which includes meters 200 that had a power outage event and/or meter removal event during the time period. The theft-detection algorithm then determines “List C” which includes meters 200 specified in the transformer discrepancy list 326. The theft-detection algorithm then determines “List D” which includes meters 200 that are included in both List B and List C. Thus, each meter 200 on List D could be a meter 200 that has been removed from its assigned service point (as indicated by List B) and has been installed to a different service point (as indicated by List C). Therefore, there is a reasonable level of confidence at this point that each meter 200 on List D is a stolen meter and can be flagged as such. However, in some embodiments, the theft-detection algorithm includes one or more double-checking steps that can be implemented separately or in combination to increase the confidence that the flagged meters are in fact stolen meters. In particular, the theft-detection algorithm can identify each meter 200 on List D that meets/satisfies one or more distance criteria relative to at least one location on a list of locations associated with List A, and flags/identifies each meter 200 satisfying the one or more distance criteria as a potential stolen meter and flags/identifies the at least one location as a potential location where the stolen meter is currently being used.

At least one technical advantage of the disclosed techniques is that, with the disclosed techniques, stolen meters and current locations of stolen meters can be automatically and systematically detected more quickly and with higher accuracy than conventional techniques. Because the disclosed techniques rely on a theft-detection algorithm that is executed automatically at the central server based on information collected from the central data store and the plurality of utility meters, the disclosed techniques do not rely on the highly random and inaccurate human detection of stolen meters, thus enabling detection of a greater number of stolen meters relative to conventional techniques. Also, because the theft-detection algorithm includes double-checking steps that increase the confidence in the flagged meters, the disclosed techniques also reduce the incidence of false positives where meters are erroneously flagged as stolen meters relative to conventional techniques. In this manner, utility providers can identify stolen meters within a reasonable time, which allows for faster recovery of the stolen meters, reduces the number of incorrect billings to customers at service points where the meters were stolen, and reduces fire hazards at service points where stolen meters were incorrectly installed.
1. In some embodiments, a method comprises generating, by a central server, a list of locations where a stolen meter is likely to be used, identifying, by the central server, a first meter having one or more characteristics of a stolen meter, and in response to determining that a first location associated with the first meter meets one or more distance criteria relative to a second location on the list of locations, performing, by the central server, a remedial action in relation to the first meter.
2. The method of clause 1, wherein the remedial action specifies an inspection of the first meter at the second location.
3. The method of clauses 1 or 2, wherein the list of locations where a stolen meter is likely to be used comprises a list of locations associated with meters that have been remote disconnected by the central server.
4. The method of any of clauses 1-3, wherein the one or more characteristics of a stolen meter include a meter having at least one of a power outage event or a meter removal event.
5. The method of any of clauses 1-4, wherein the one or more characteristics of a stolen meter include a meter having a discrepancy between an initially assigned transformer and a currently connected transformer.
6. The method of any of clauses 1-5, wherein meeting the one or more distance criteria include determining that the first location associated with the first meter is within a threshold distance from the second location on the list of locations.
7. The method of any of clauses 1-6, wherein the first location associated with the first meter comprises a location of a first transformer that is initially assigned to the first meter and the second location comprises a location of a second transformer that is initially assigned to a second meter that has a remote disconnect event.
8. The method of any of clauses 1-7, wherein meeting the one or more distance criteria include determining that the first location associated with the first meter overlaps the second location on the list of locations.
9. The method of any of clauses 1-8, wherein the first location associated with the first meter comprises a location of a first transformer that is currently connected to the first meter and the second location comprises a location of a second transformer that is initially assigned to a second meter that has a remote disconnect event.
10. In some embodiments, one or more non-transitory computer-readable media include instructions that, when executed by one or more processors, cause the one or more processors to perform operations comprising determining a list of locations where a stolen meter is likely to be installed, identifying a first meter having one or more properties of a stolen meter, and in response to determining that a first location associated with the first meter meets one or more distance criteria relative to a second location on the list of locations, executing a remedial action in relation to the first meter.
11. The one or more non-transitory computer-readable media of clause 10, wherein the remedial action includes at least one of causing an inspection of the first meter at the second location, generating a work order for a utility worker regarding the first meter at the second location, or cause the first meter at the second location to be remote disconnected.
12. The one or more non-transitory computer-readable media of clauses 10 or 11, wherein the list of locations where a stolen meter is likely to be used comprises a list of locations associated with meters that have reported a remote disconnect event.
13. The one or more non-transitory computer-readable media of any of clauses 10-12, wherein the one or more properties of a stolen meter include a meter having at least one of a power outage event or a meter removal event.
14. The one or more non-transitory computer-readable media of any of clauses 10-13, wherein the one or more properties of a stolen meter include a meter having a discrepancy between an initially assigned transformer and a currently connected transformer.
15. The one or more non-transitory computer-readable media of any of clauses 10-14, wherein meeting the one or more distance criteria include determining that the first location associated with the first meter is within a predetermined threshold distance from the second location on the list of locations.
16. In some embodiments, a computer system comprises one or more processors, and a memory storing executable instructions that, when executed by the one or more processors, cause the one or more processors to perform operations comprising computing a list of service points where a stolen utility meter is likely to be used, determining a first utility meter having one or more characteristics of a stolen utility meter, and in response to determining that a first service point associated with the first utility meter meets one or more distance criteria relative to a second service point on the list of service points, performing a remedial action in relation to the first utility meter.
17. The computer system of clause 16, wherein the remedial action specifies an inspection of the first utility meter at the second service point.
18. The computer system of clauses 16 or 17, wherein the list of service points where a stolen utility meter is likely to be used comprises a list of service points associated with utility meters that have been remote disconnected by a central server.
19. The computer system of any of clauses 16-18, wherein the one or more characteristics of a stolen utility meter include a utility meter having at least one of a power outage event or a meter removal event.
20. The computer system of any of clauses 16-19, wherein the one or more characteristics of a stolen utility meter include a utility meter having a discrepancy between an initially assigned transformer and a currently connected transformer.

Any and all combinations of any of the claim elements recited in any of the claims and/or any elements described in this application, in any fashion, fall within the contemplated scope of the present protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments can be embodied as a system, method or computer program product. Accordingly, aspects of the present disclosure can take the form of an entirely hardware embodiment, an entirely software embodiment (including firmware, resident software, micro-code, etc.) or an embodiment combining software and hardware aspects that can all generally be referred to herein as a “module,” a “system,” or a “computer.” In addition, any hardware and/or software technique, process, function, component, engine, module, or system described in the present disclosure can be implemented as a circuit or set of circuits. Furthermore, aspects of the present disclosure can take the form of a computer program product embodied in one or more computer readable medium(s) having computer readable program code embodied thereon.

Any combination of one or more computer readable medium(s) can be utilized. The computer readable medium can be a computer readable signal medium or a computer readable storage medium. A computer readable storage medium can be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium can be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions can be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors can be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams can represent a module, segment, or portion of code, which comprises one or more executable instructions for implementing the specified logical function(s). It should also be noted that, in some alternative implementations, the functions noted in the block can occur out of the order noted in the figures. For example, two blocks shown in succession can, in fact, be executed substantially concurrently, or the blocks can sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure can be devised without departing from the basic scope thereof, and the scope thereof is determined by the claims that follow. Moreover, in the above description, numerous specific details are set forth to provide a more thorough understanding of the various embodiments. However, it will be apparent to one of skill in the art that the inventive concepts may be practiced without one or more of these specific details.

What is claimed is:

1. A method comprising:
generating, by a central server, a list of locations where a stolen meter is likely to be used;
identifying, by the central server, a first meter having one or more characteristics of a stolen meter; and
in response to determining that a first location associated with the first meter meets one or more distance criteria relative to a second location on the list of locations, performing, by the central server, a remedial action in relation to the first meter.

2. The method of claim 1, wherein the remedial action specifies an inspection of the first meter at the second location.

3. The method of claim 1, wherein the list of locations where a stolen meter is likely to be used comprises a list of locations associated with meters that have been remote disconnected by the central server.

4. The method of claim 1, wherein the one or more characteristics of a stolen meter include a meter having at least one of a power outage event or a meter removal event.

5. The method of claim 1, wherein the one or more characteristics of a stolen meter include a meter having a discrepancy between an initially assigned transformer and a currently connected transformer.

6. The method of claim 1, wherein meeting the one or more distance criteria include determining that the first location associated with the first meter is within a threshold distance from the second location on the list of locations.

7. The method of claim 6, wherein the first location associated with the first meter comprises a location of a first transformer that is initially assigned to the first meter and the second location comprises a location of a second transformer that is initially assigned to a second meter that has a remote disconnect event.

8. The method of claim 1, wherein meeting the one or more distance criteria include determining that the first location associated with the first meter overlaps the second location on the list of locations.

9. The method of claim 8, wherein the first location associated with the first meter comprises a location of a first transformer that is currently connected to the first meter and the second location comprises a location of a second transformer that is initially assigned to a second meter that has a remote disconnect event.

10. One or more non-transitory computer-readable media including instructions that, when executed by one or more processors, cause the one or more processors to perform operations comprising:
determining a list of locations where a stolen meter is likely to be installed;
identifying a first meter having one or more properties of a stolen meter; and
in response to determining that a first location associated with the first meter meets one or more distance criteria relative to a second location on the list of locations, executing a remedial action in relation to the first meter.

11. The one or more non-transitory computer-readable media of claim 10, wherein the remedial action includes at least one of causing an inspection of the first meter at the second location, generating a work order for a utility worker regarding the first meter at the second location, or cause the first meter at the second location to be remote disconnected.

12. The one or more non-transitory computer-readable media of claim 10, wherein the list of locations where a stolen meter is likely to be used comprises a list of locations associated with meters that have reported a remote disconnect event.

13. The one or more non-transitory computer-readable media of claim 10, wherein the one or more properties of a stolen meter include a meter having at least one of a power outage event or a meter removal event.

14. The one or more non-transitory computer-readable media of claim 10, wherein the one or more properties of a stolen meter include a meter having a discrepancy between an initially assigned transformer and a currently connected transformer.

15. The one or more non-transitory computer-readable media of claim 10, wherein meeting the one or more distance criteria include determining that the first location associated with the first meter is within a predetermined threshold distance from the second location on the list of locations.

16. A computer system comprising:
one or more processors; and
a memory storing executable instructions that, when executed by the one or more processors, cause the one or more processors to perform operations comprising:
computing a list of service points where a stolen utility meter is likely to be used;
determining a first utility meter having one or more characteristics of a stolen utility meter; and
in response to determining that a first service point associated with the first utility meter meets one or more distance criteria relative to a second service point on the list of service points, performing a remedial action in relation to the first utility meter.

17. The computer system of claim 16, wherein the remedial action specifies an inspection of the first utility meter at the second service point.

18. The computer system of claim 16, wherein the list of service points where a stolen utility meter is likely to be used comprises a list of service points associated with utility meters that have been remote disconnected by a central server.

19. The computer system of claim 16, wherein the one or more characteristics of a stolen utility meter include a utility meter having at least one of a power outage event or a meter removal event.

20. The computer system of claim 16, wherein the one or more characteristics of a stolen utility meter include a utility meter having a discrepancy between an initially assigned transformer and a currently connected transformer.
